(19) United States
(12) Patent Application Publication
(10) Pub. No.: US 2013/0175514 A1
(43) Pub. Date: Jul. 11, 2013

(54) DISPLAY DEVICE

(71) Applicant: SAMSUNG DISPLAY CO., LTD., Yongin-city (KR)

(72) Inventors: Kyul HAN, Yongin-city (KR); O-Hyun KWON, Yongin-city (KR); Dong-woo SHIN, Yongin-city (KR); Seul-Ong KIM, Yongin-city (KR); Byoung-Ki CHOI, Yongin-city (KR)

(73) Assignee: SAMSUNG DISPLAY CO., LTD., Yongin-city (KR)

(21) Appl. No.: 13/729,941

(22) Filed: Dec. 28, 2012

(30) Foreign Application Priority Data
Jan. 9, 2012 (KR) 10-2012-0002552

(51) Int. Cl. H01L 27/32

(52) U.S. Cl. CPC H01L 27/3213
USPC 257/40

(57) ABSTRACT

A display device includes a substrate and a pixel formed over the substrate. The pixel includes a red subpixel, a green subpixel, a deep green subpixel, and a blue subpixel. The configuration of the display device increases the luminous efficiency and life-span and realizes the high color purity.

### RELATED APPLICATIONS

This application claims priority to and the benefit of Korean Patent Application No. 10-2012-0002552 filed in the Korean Intellectual Property Office on Jan. 9, 2012, the entire contents of which are incorporated herein by reference.

### BACKGROUND

1. Field

The described technology relates generally to a display device.

2. Discussion of the Related Technology

As flat panel displays that are widely known, there are a liquid crystal display (LCD), a plasma display device (PDP), an organic light emitting diode (OLED) display, an electric field effect display (FED), and an electrophoretic display device.

Among them, the organic light emitting diode (OLED) display includes two electrodes and an organic emission layer disposed between the two electrodes, and electrons injected from one electrode and holes injected from the other electrode are combined in the organic emission layer such that excitons are formed such that light is emitted by energy generated from the excitons.

Color reproducibility of the organic light emitting diode (OLED) display depends on determining whether a colorimetric range of the organic light emitting diode (OLED) display satisfies a standard colorimetric range of an NTSC standard or an sRGB standard in the CIE (Commission Internationale de l'Eclairage) chromaticity 1931 colorimetric system or the CIE 1976 colorimetric system.

In an HDTV (high definition television) format, a display device satisfying the standard colorimetric range of the sRGB standard is required such that CIE color coordinates of three primary colors of red R, green G, and blue B of the sRGB standard satisfies R (0.64 and 0.33), G (0.30 and 0.60), and B (0.15 and 0.06).

If the light emitted from the organic emission layer does not satisfy the CIE color coordinates, the light emitted from the organic emission layer is filtered through a color filter for the satisfaction of the CIE color coordinates or a predetermined wavelength is reinforced through a microcavity effect such that the filtered light satisfies the CIE color coordinates.

However, in an UHDTV (ultra high definition television) format, to realize a beautiful image as well as high definition, the colorimetric range thereof is wider than the standard colorimetric range of the sRGB standard. Accordingly, it is difficult for the display device only satisfying the standard colorimetric range of the conventional sRGB standard to be applied to the UHDTV format.

Accordingly, in the UHDTV format, a deep red (dR), a deep green (dG), and a deep blue (dB) having high color purity are required. For this, when changing the green among the color coordinates of the sRGB standard, a maximum standard colorimetric range may be expanded. That is, in the UHDTV format, at least the deep green color coordinates dG (0.21, 0.71) of the NTSC standard may be required, and higher color purity may be required. As described above, the color purity of the deep red and the deep blue is similar to the conventional red and blue, however the color purity of the deep green is different from the conventional green.

When the light emitted from the organic emission layer does not satisfy the color coordinates required for the UHDTV format, the color coordinates of the deep red (dR), the deep green (dG), and the deep blue (dB) may be satisfied by the color filter or the microcavity effect. However, in this case, additional equipments may be provided, and thus the costs would be increased.

To realize the deep green satisfying the color coordinates required for the UHDTV format, a peak wavelength of the deep green emitted from the organic emission layer is lower than about 555 nm. Also, the peak wavelength is fixed and the light-emitting of the wavelength range higher than the peak wavelength is suppressed by reducing the spectrum width to realize the deep green.

However, in this case, the peak wavelength is lower than about 555 nm as the wavelength that is most sensitive to eyes such that visibility of the eyes is deteriorated. Also, the spectrum width is decreased such that the waveform becomes thin, and then the light-emitting of a certain wavelength region is suppressed to realize the deep green, and thus, an exciton is generated with a further higher energy.

Accordingly, in the case of the display device realizing the deep green satisfying the color coordinates required for the UHDTV format, luminous efficiency and life-span are deteriorated when compared with the luminous efficiency and the life-span of the display device satisfying the standard colorimetric range of the sRGB standard.

The above information disclosed in this Background section is only for enhancement of understanding of the background of the described technology and therefore it may contain information that does not form the prior art that is already known in this country to a person of ordinary skill in the art.

### SUMMARY

One aspect of the present invention provides a display device with improved luminous efficiency and life-span and high color purity.

A display device according to an embodiment includes a substrate, and a pixel formed over the substrate and including a red subpixel, a green subpixel, a deep green subpixel, and a blue subpixel.

The pixel may include at least a first electrode formed over the substrate, a plurality of organic emission layers formed over the at least a first electrode and including a red organic emission layer positioned at the red subpixel, a green organic emission layer positioned at the green subpixel, a deep green organic emission layer positioned at the deep green subpixel, and a blue organic emission layer positioned at the blue subpixel, and at least a second electrode formed over the plurality of organic emission layers.

The green organic emission layer may be configured to emit green light having a y-axis color coordinate Gy of green light greater than about 0.45, and the deep green organic emission layer may be configured to emit deep green light having a y-axis color coordinate dGy which satisfies dGy≧Gy+0.01.

The green organic emission layer may be configured to emit green light having a y-axis color coordinate Gy greater than 0.45, and the deep green organic emission layer may be configured to emit deep green light having an x-axis color coordinate dGx that satisfies Gx≧dGx+0.01, where Gx is an x-axis color coordinate of the green light emitted from the green organic emission layer.

The green organic emission layer may be configured to emit green light having a peak wavelength λpg of the green light's spectrum, and the deep green organic emission layer may be configured to emit deep green light having a peak wavelength λpdg of the deep green light's spectrum, wherein the peak wave lengths λpg and λpdg may satisfy λpdg, λpg−λpdg≧1 nm.

The green organic emission layer may be configured to emit green light having a spectrum width Wg which is a full width at quarter maximum (FWQM) of the green light's spectrum, and the deep green organic emission layer may be configured to emit deep green light having a spectrum width Wdg which is a FWQM of the deep green light's spectrum, wherein the spectrum widths Wg and Wdg satisfies Wg−Wdg≧1 nm.

The green organic emission layer may be configured to emit green light having a spectrum half width Whg at a half of the maximum intensity of the green light's spectrum, and the deep green organic emission layer may be configured to emit deep green light having a spectrum width Whdg which is a FWHM of the deep green light's spectrum, wherein the spectrum widths Whg and Whdg may satisfy Whg−Whdg≧1 nm may be satisfied.

The green organic emission layer may include a phosphor material or a phosphorescent material, and the deep green organic emission layer may include a phosphor material or a phosphorescent material.

The deep green organic emission layer may include a quantum dot.

The pixel may include at least a first electrode formed over the substrate, a plurality of organic emission layers formed over the at least a first electrode and including a red organic emission layer positioned at the red subpixel, a first green organic emission layer positioned at the green subpixel, a second green organic emission layer positioned at the deep green subpixel, and a blue organic emission layer positioned at the blue subpixel, at least a second electrode formed over the plurality of organic emission layers, and a deep green color filter formed over the second green emission layer positioned at the deep green subpixel.

The pixel may include at least a first electrode formed over the substrate, a plurality of organic emission layers formed over the at least one first electrode and including a red organic emission layer positioned at the red subpixel, a first green organic emission layer positioned at the green subpixel, a second green organic emission layer positioned at the deep green subpixel, and a blue organic emission layer positioned at the blue subpixel, at least a second electrode formed over the plurality of organic emission layers, and a microcavity structure formed between the at least a first electrode and the second green organic emission layer positioned at the deep green subpixel.

One of the red subpixel, the green subpixel, the deep green subpixel, and the blue subpixel may have an area different from that of another subpixel.

The red subpixel, the green subpixel, the deep green subpixel, and the blue subpixel may be shaped and arranged such that the pixel has one selected from a stripe type arrangement, a quadrangle type arrangement, and a pentile type arrangement.

Accordingly, the display device according to an embodiment includes the red subpixel, the green subpixel, the deep green subpixel, and the blue subpixel, thereby increasing the luminous efficiency and life-span and realizing the high color purity.

### BRIEF DESCRIPTION OF THE DRAWINGS

FIG. 1 is a top plan view of one pixel of a display device according to the first embodiment.

FIG. 2 is a CIE 1931 colorimetric system showing color coordinates of a deep green pixel of a display device according to the first embodiment.

FIG. 3 is a layout view of one pixel of a display device according to the first embodiment.

FIG. 4 is a cross-sectional view of the display device of FIG. 3 taken along the line IV-IV.

FIG. 5 is a view showing a green light spectrum of a green subpixel and a deep green light spectrum of a deep green subpixel in a display device according to the first embodiment.

FIG. 6 is a graph showing a change of luminance according to time of each subpixel in a comparative example of a display device including a red subpixel, a green subpixel, and a blue subpixel.

FIG. 7 is a graph showing a change of luminance according to time of a pixel under full white in the display device of FIG. 6.

FIG. 8 is a graph showing a change of luminance according to time of each subpixel in a display device including a red subpixel, a deep green subpixel, and a blue subpixel.

FIG. 9 is a graph showing a change of a luminance according to time of a pixel under full white in the display device of FIG. 8.

FIG. 10 is a graph showing a change of luminance according to time of each subpixel in a display device according to the first embodiment including a red subpixel, a green subpixel, a deep green subpixel, and a blue subpixel.

FIG. 11 is a graph showing a change of luminance according to time of a pixel under full white in the display device of FIG. 10.

FIG. 12 is a top plan view of one pixel of a display device according to the second embodiment.

FIG. 13 is a top plan view of two pixels of a display device according to the third embodiment.

FIG. 14 is a cross-sectional view of a deep green subpixel of a display device according to the fourth embodiment.

FIG. 15 is a cross-sectional view of a deep green subpixel of a display device according to the fifth embodiment.

### DETAILED DESCRIPTION

Embodiments of the present invention will be described more fully hereinafter with reference to the accompanying drawings, in which embodiments of the invention are shown. As those skilled in the art would realize, the described embodiments may be modified in various different ways, all without departing from the spirit or scope of the present invention.

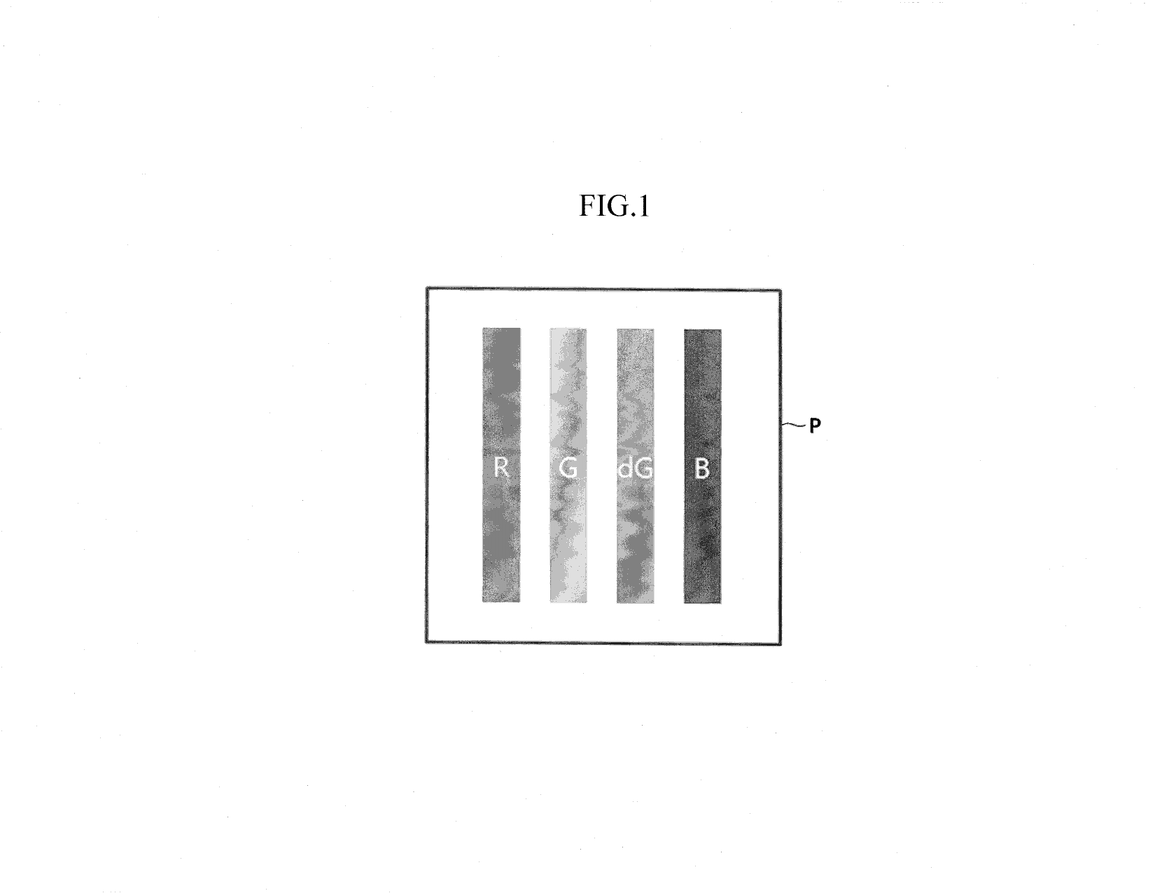

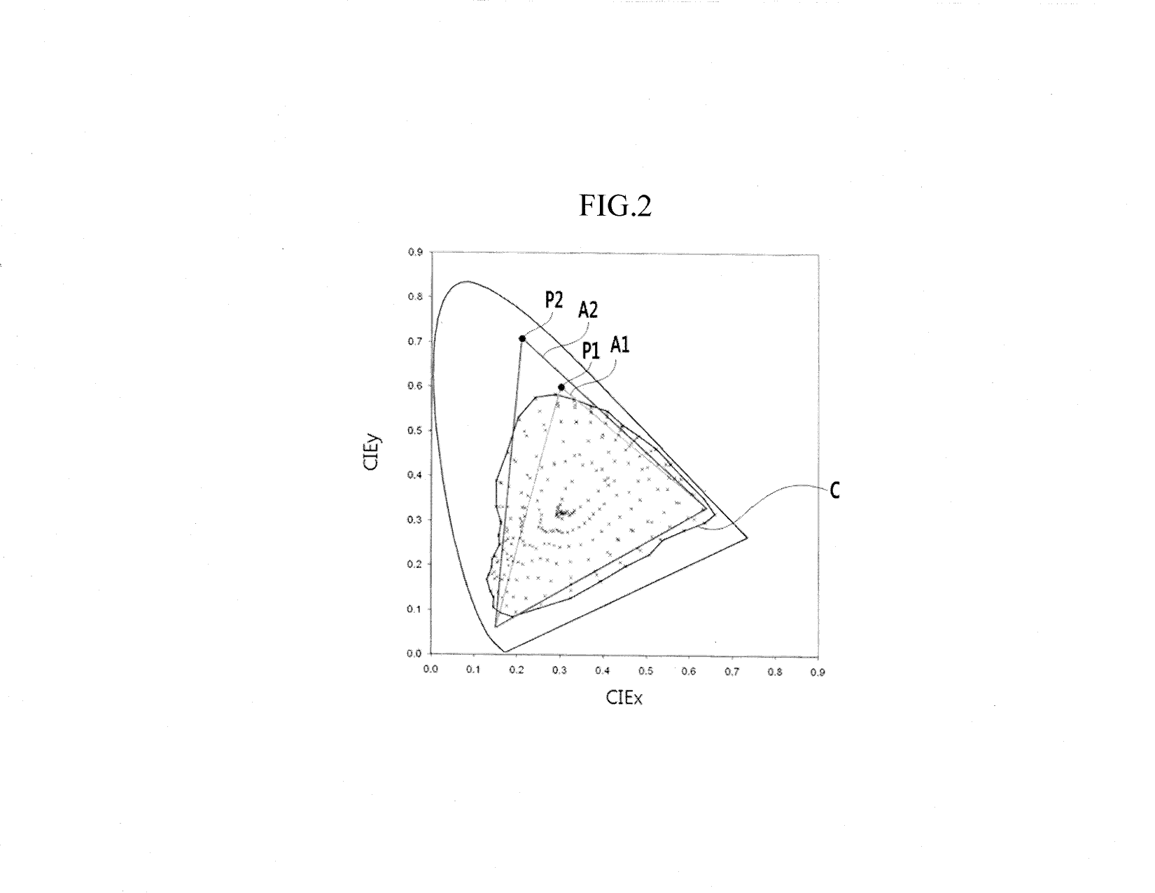

FIG. 1 is a top plan view of one pixel of a display device according to the first embodiment, and FIG. 2 is a CIE 1931 colorimetric system showing color coordinates of a deep green pixel of a display device according to the first embodiment.

As shown in FIG. 1, one pixel P of a display device according to the first embodiment includes a red subpixel R, a green subpixel G, a deep green subpixel dG, and a blue subpixel B. The red subpixel R light-emits red, the green subpixel G light-emits green, the deep green subpixel dG light-emits deep green having color purity, and the blue subpixel B light-emits blue. In embodiments, the red subpixel R, the green subpixel G, the deep green subpixel dG, and the blue subpixel B are arranged side by side to form a stripe type arrangement. That is, each of the red subpixel R, the green subpixel G, the deep green subpixel dG, and the blue subpixel B has a rectangular stripe shape and form a pixel P of a square shape through a combination thereof. At this time, to compensate the different luminous efficiencies and life-spans between the red subpixel R, one of the green subpixel G, the deep green subpixel dG, and the blue subpixel B, areas of the red subpixel R, the green subpixel G, the deep green subpixel dG, and the blue subpixel B may have area different from that of another subpixel.

As shown in FIG. 2, CIE 1931 color coordinates of the green light emitted from the green subpixel are defined as (Gx, Gy), and CIE 1931 color coordinates of the deep green light emitted from the deep green subpixel are defined as (dGx, dGy), while a y-axis color coordinate Gy of the green light is equal to or greater than about 0.45.

In embodiment, the y-axis color coordinate dGy of the deep green light may be greater than the y-axis color coordinate Gy of the green light by at least about 0.01, or the x-axis color coordinate dGx of the deep green light may be smaller than the x-axis color coordinate Gx of the green light by at least about 0.01. This may be represented by Equation 1 below.

dGy≧Gy+0.01 or Gx≧dGx+0.01 (Equation 1)

Also, dGy may be greater than Gy by at least about 0.01, and simultaneously dGx may be smaller than Gx by at least about 0.01. This may be represented by Equation 2 below.

dGy≧Gy+0.01 and Gx≧dGx+0.01 (Equation 2)

FIG. 2 is a CIE 1931 colorimetric system showing a triangle A1 representing a standard colorimetric range of an sRGB standard and a triangle A2 representing a standard colorimetric range of an NTSC standard.

As shown in FIG. 2, the green corresponds to the color coordinates P1 (0.30 and 0.60) inside the triangle A1 representing the standard colorimetric range of the sRGB standard, and the deep green corresponds to the color coordinates P2 (0.21 and 0.71) in the triangle A2 representing the standard colorimetric range of the NTSC standard.

In this case, dGy is greater than Gy by a value greater than 0.01, and simultaneously dGx is smaller than Gx by a value greater than 0.01.

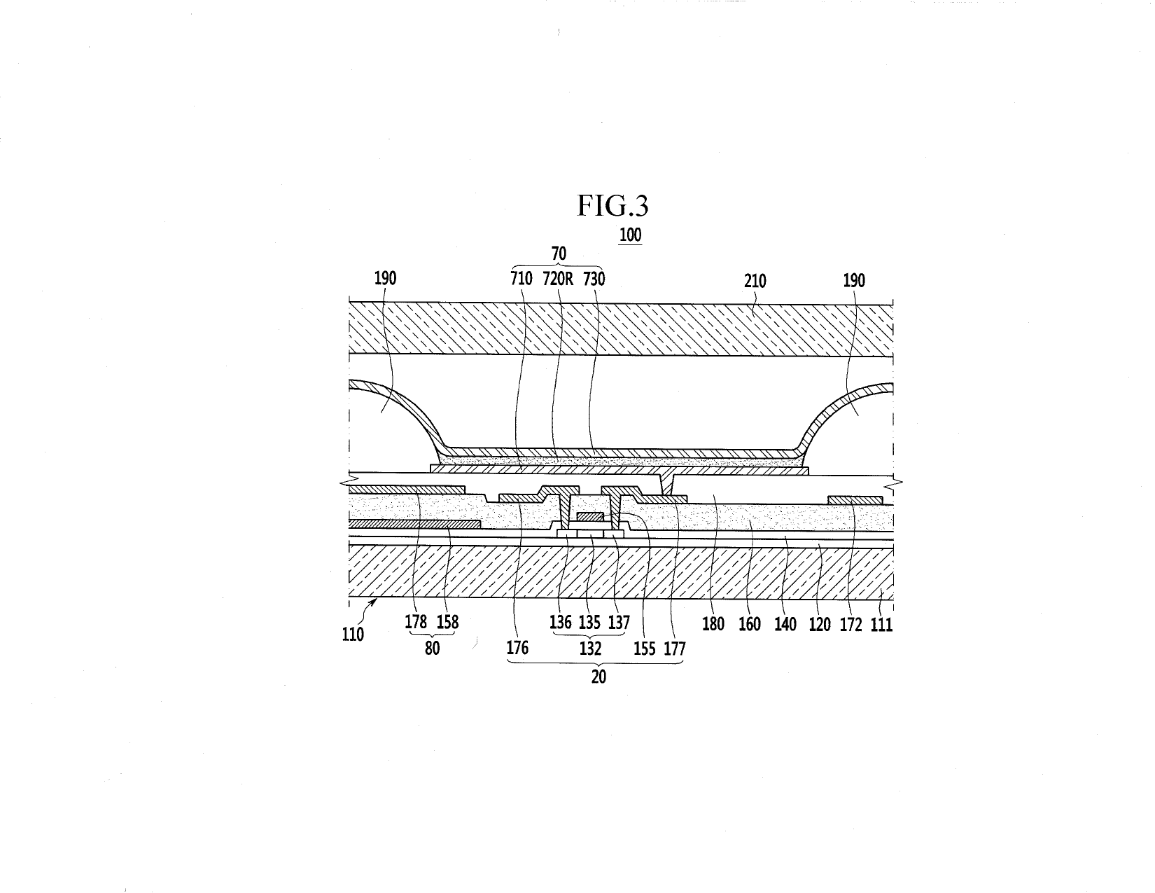

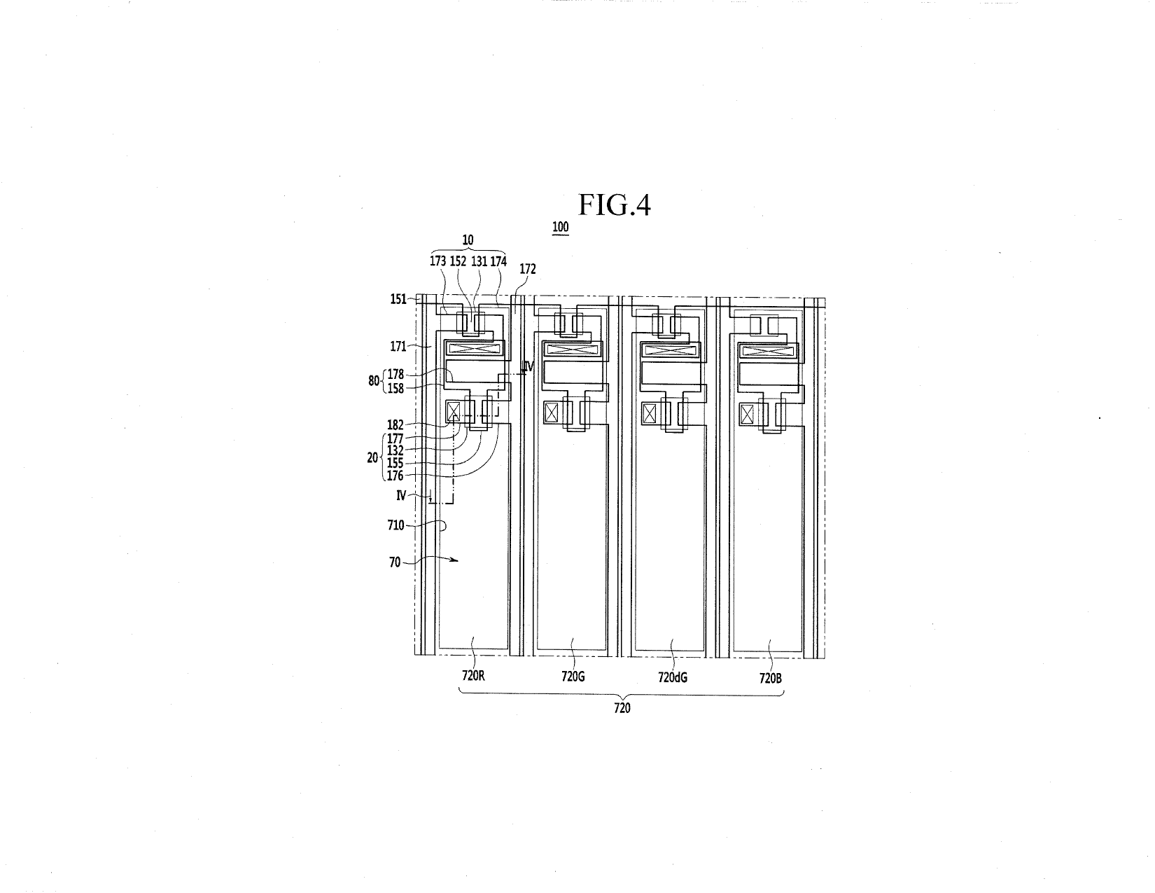

Next, a structure of one pixel of a display device according to the first embodiment will be described in detail with reference to FIG. 3 and FIG. 4.

FIG. 3 is a layout view of one pixel of a display device according to the first embodiment, and FIG. 4 is a cross-sectional view of the display device of FIG. 3 taken along the line IV-IV.

As shown in FIG. 3 and FIG. 4, a display substrate 110 of a display device according to the first embodiment is provided and subpixels are formed on the substrate 110. Each subpixel includes a switching thin film transistor 10, a driving thin film transistor 20, a capacitor 80, and an organic light emitting element 70. Also, the display device further includes a gate line 151 extending along one direction, a data line 171 insulated from and intersecting the gate line 151, and a common power source line 172. Here, one subpixel may be defined by the gate line 151, the data line 171, and the common power source line 172, however the invention is not limited thereto.

Referring to FIGS. 3 and 4, in embodiments, in each subpixel, the organic light emitting element 70 includes a first electrode 710, an organic emission layer 720 (720R, 720G, 720dG or 720B) formed on the first electrode 710, and a second electrode 730 formed on the organic emission layer 720. Here, the first electrode 710 is a positive (+) electrode as a hole injection electrode, and the second electrode 730 is a negative (−) electrode as an electron injection electrode. A hole and an electron are injected inside the organic emission layer 720 from the first electrode 710 and the second electrode 730, respectively. When excitons of which the injected holes and electrons are coupled fall from an exited state to a ground state, light is emitted. In embodiments, a pixel may have a common electrode which functions as the second electrode of each subpixel.

The capacitor 80 includes a first capacitive plate 158 and a second capacitive plate 178 that are disposed with an interlayer insulating layer 160 disposed therebetween. Here, the interlayer insulating layer 160 becomes a dielectric material. Storage capacity is determined by electric charges stored in the storage capacitor 80 and a voltage between the storage plates 128 and 178.

The switching thin film transistor 10 includes a switching semiconductor layer 131, a switching gate electrode 152, a switching source electrode 173, and a switching drain electrode 174, and the driving thin film transistor 20 includes a driving semiconductor layer 132, a driving gate electrode 155, a driving source electrode 176, and a driving drain electrode 177.

The switching thin film transistor 10 is used as a switching element for selecting a pixel to emit light. The switching gate electrode 152 is connected to the gate line 151. The switching source electrode 173 is connected to the data line 171. The switching drain electrode 174 is separated from the switching source electrode 173 and is connected to the first capacitive plate 158.

The driving thin film transistor 20 applies driving power for allowing the organic emission layer 720 of the organic light emitting diode 70 in the selected pixel to emit light to the pixel electrode 710. The driving gate electrode 155 is connected to the first capacitive plate 158. The driving source electrode 176 and the second capacitive plate 178 are respectively connected to the common power source line 172. The driving drain electrode 177 is connected to the first electrode 710 of the organic light emitting element 70 through a contact hole 182.

By this structure, the switching thin film transistor 10 is operated by a gate voltage applied to the gate line 121 to serve to transmit a data voltage applied to the data line 171 to the driving thin film transistor 20. A voltage equivalent to a difference between a common voltage applied to the driving thin film transistor 20 from the common power source line 172 and a data voltage transmitted from the switching thin film transistor 10 is stored in the storage capacitor 80, and a current corresponding to a voltage stored in the storage capacitor 80 flows to the organic light emitting diode 70 through the driving thin film transistor 20 to allow the organic light emitting diode 70 to emit light.

Next, referring to FIG. 4, a structure of an organic light emitting diode (OLED) display according to the first embodiment will be described according to a deposition sequence.

In embodiments, a first substrate member 111 that forms the display substrate 110 is formed of an insulating substrate that is made of glass, quartz, ceramic, plastic, or the like. A buffer layer 120 is formed on the first substrate member 111. The buffer layer 120 prevents impurities from permeating and planarizes the surface, and may be formed of various materials that can perform these functions. A driving semiconductor layer 132 is formed on the buffer layer 120. The driving semiconductor layer 132 is formed of a polysilicon layer. In addition, the driving semiconductor layer 132 includes a channel region 135 in which an impurity is not doped, and a source region 136 and a drain region 137 that are p+ doped at respective sides of the channel region 135. A gate insulating layer 140 that is formed of silicon nitride (SiNx) or silicon oxide (SiO2) is formed on the driving semiconductor layer 132. Gate wiring that includes the driving gate electrode 155 is formed on the gate insulating layer 140. In addition, the gate wiring further includes the gate line 151, the first capacitor plate 158, and other wiring. Further, the driving gate electrode 155 is formed so as to overlap at least a portion of the driving semiconductor layer 132, particularly the channel region 135.

The interlayer insulating layer 160 that covers the driving gate electrode 155 is formed on the gate insulating layer 140. The gate insulating layer 140 and the interlayer insulating layer 160 have through-holes that expose the source region 136 and the drain region 137 of the driving semiconductor layer 132. The interlayer insulating layer 160, like the gate insulating layer 140, is made of a ceramic-based material such as silicon nitride (SiNx) or silicon oxide (SiO2).

Data wiring including the driving source electrode 176 and the driving drain electrode 177 is formed on the interlayer insulating layer 160. In addition, the data wiring further includes the data line 171, the driving voltage line 172, the second capacitor plate 178, and other wiring. In addition, the driving source electrode 176 and driving drain electrode 177 are connected to the source region 136 and the drain region 137 of the driving semiconductor layer 132 through the through-holes that are formed on the interlayer insulating layer 160 and gate insulating layer 140.

As described above, the driving thin film transistor 20 that includes the driving semiconductor layer 132, the driving gate electrode 155, the driving source electrode 176, and the driving drain electrode 177 is formed. The constitution of the driving thin film transistor 20 is not limited to the above examples, but may be variously modified with known constitutions that can be easily performed by those who are skilled in the art.

A protective layer 180 that covers the data wires 172, 176, 177, and 178 is formed on the interlayer insulating layer 160. The planarization layer 180 functions to reduce and flatten a step to increase luminous efficiency of the organic light emitting element 70 that will be formed later. Also, the planarization layer 180 has the electrode contact hole 182 exposing a portion of the drain electrode 177.

In embodiments, the first electrode 710 of the organic light emitting element 70 is formed on the planarization layer 180. That is, the organic light emitting diode (OLED) display 100 includes a plurality of the first electrodes 710 respectively disposed for a plurality of pixels. A plurality of the first electrodes 710 are disposed to be separated from each other. The first electrode 710 is connected to the drain electrode 177 through the electrode contact hole 182 of the planarization layer 180.

Also, a pixel definition layer 190 forming an opening in the first electrode 710 is formed on the planarization layer 180. That is, the pixel definition layer 190 has a plurality of openings that are individually formed for each pixel. In addition, the first electrode 710 is disposed so as to correspond to the opening of the pixel definition layer 190. The organic emission layer 720 is formed on the first electrode 710, and the second electrode 730 is formed on the organic emission layer 720. As described above, the organic light emitting element 70 including the first electrode 710, the organic emission layer 720, and the second electrode 730 is formed.

The organic emission layer 720 is made of a low molecular weight organic material or a high molecular weight organic material. Also, the organic emission layer 720 can be formed with multiple layers including at least one of an emission layer, a hole injection layer (HIL), a hole transport layer (HTL), an electron transport layer (ETL), and an electron injection layer (EIL). When all layers are included, the hole injection layer (HIL) is disposed on the pixel electrode 710, and an anode, and then the hole transport layer (HTL), the emission layer, the electron transport layer (ETL), and the electron injection layer (EIL) are sequentially stored thereon.

In embodiments, the first electrode 710 and the second electrode 730 may be formed of a transparent conductive material, respectively, or a semitransparent or reflective conductive material. According to the kind of the material that forms the first electrode 710 and the second electrode 730, the organic light emitting diode (OLED) display 100 may be a front surface light emitting type, a rear surface light emitting type, or both surface light emitting type.

On the second electrode 730, an encapsulation substrate 210 is arranged opposite to the display substrate 110. The encapsulation substrate 210 is a substrate that encapsulates at least the display area (DA) in the display substrate 110 in which the organic light emitting element is formed, and in the case that it is a front surface light emitting type or a both surface light emitting type, it is formed of a transparent material such as glass or plastic, while in the case that it is a rear surface light emitting type, it is formed of an opaque material such as a metal. This encapsulation substrate 210 has a plate shape.

The organic emission layers 720 include a red organic emission layer 720R, a green organic emission layer 720G, a deep green organic emission layer 720dG, and a blue organic emission layer 720B. In embodiments, the green organic emission layer 720G may include a phosphor material or a phosphorescent material, and the deep green organic emission layer 720G may include a phosphor material or a phosphorescent material.

The deep green organic emission layer 720dG may include quantum dots to increase color purity.

In this description, the peak wavelength (a wavelength having the maximum intensity) of the red light spectrum of the red subpixel is referred to as λpr, the peak wavelength of the green light spectrum of the green subpixel is referred to as λpg, the peak wavelength of the deep green light spectrum of the deep green subpixel is referred to as λpdg, the peak wavelength of the blue light spectrum of the blue subpixel is referred to as λpb, and a spectrum width (full width at quarter maximum (FWQM) which is a difference between first and second wavelengths, each of which has intensity equal to a quarter of the maximum intensity) of a quarter intensity of each light spectrum is referred as Wr, Wg, Wdg, and Wb. In embodiments, λpr is about 600 nm to about 700 nm, each of λpg and λpdg is about 500 nm to 600 nm, and λpb is about 400 nm to 500 nm. Also, each of Wr, Wg, Wdg, and Wb is about 25 nm to about 150 nm.

In embodiments, the peak wavelength λpdg of the deep green light spectrum of the deep green subpixel is smaller than the peak wavelength λpg of the green light spectrum of the green subpixel by at least about 1 nm, or the spectrum width Wdg of the deep green light spectrum is smaller than the spectrum width Wg of the green light spectrum by at least about 1 nm. This may be represented by Equation 3 below.

λpd−λpdg≧1 nm or Wg−Wdg≧1 nm (Equation 3)

The peak wavelength λpdg of the deep green light spectrum of the deep green subpixel is smaller than the peak wavelength λpg of the green light spectrum of the green subpixel by at least about 1 nm, and the spectrum width Wdg of the deep green light spectrum is smaller than the spectrum width Wg of the green light spectrum by at least about 1 nm. This may be represented by Equation 4 below.

λpd−λpdg≧1 nm and Wg−Wdg≧1 nm (Equation 4)

Also, a spectrum half width (full width at half maximum (FWHM) which is a difference between first and second wavelengths, each of which has intensity equal to a half the maximum intensity) (Whdg) of the deep green light spectrum of the deep green subpixel is smaller than the spectrum half width (Whg) of the green light spectrum of the green subpixel by at least about 1 nm, or the peak wavelength (λpdg) of the deep green light spectrum of the deep green subpixel is smaller than the peak wavelength (λpg) of the green light spectrum of the green subpixel by at least 1 nm, and simultaneously the spectrum half width (Whdg) of the deep green light spectrum of the deep green subpixel is smaller than the spectrum half width (Whg) of the green light spectrum of the green subpixel by 1 nm in minimum.

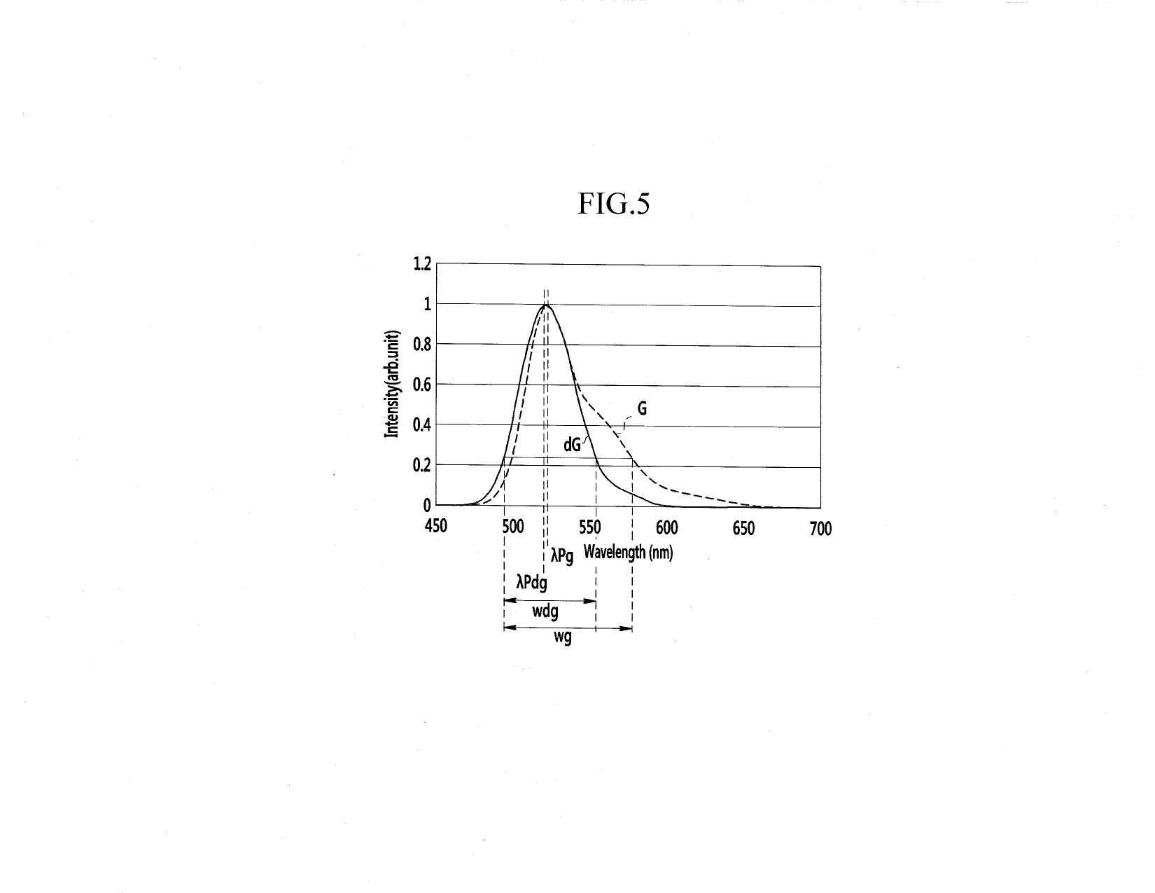

FIG. 5 is a view showing a green light spectrum of a green subpixel and a deep green light spectrum of a deep green subpixel in a display device according to the first embodiment.

As shown in FIG. 5, in an embodiment, the peak wavelength (λpg) of the green light spectrum is 523 nm, the spectrum width (Wg) of the green light spectrum is 78 nm, the peak wavelength (λpdg) of the deep green light spectrum is 522 nm, and the spectrum width (Wdg) of the deep green light spectrum is 60 nm.

Accordingly, λpg−Apdg is 1 nm and Wg−Wdg is 18 nm, thereby there is a case that the peak wavelength (λpdg) of the deep green light spectrum of the deep green subpixel is smaller than the peak wavelength (λpg) of the green light spectrum of the green subpixel by at least about 1 nm, and simultaneously the spectrum width (Wdg) of the deep green light spectrum is smaller than the spectrum width (Wg) of the green light spectrum by 1 nm.

Next, luminous efficiency, life-span, and color purity of a display device according to the first embodiment and a comparative display device will be described.

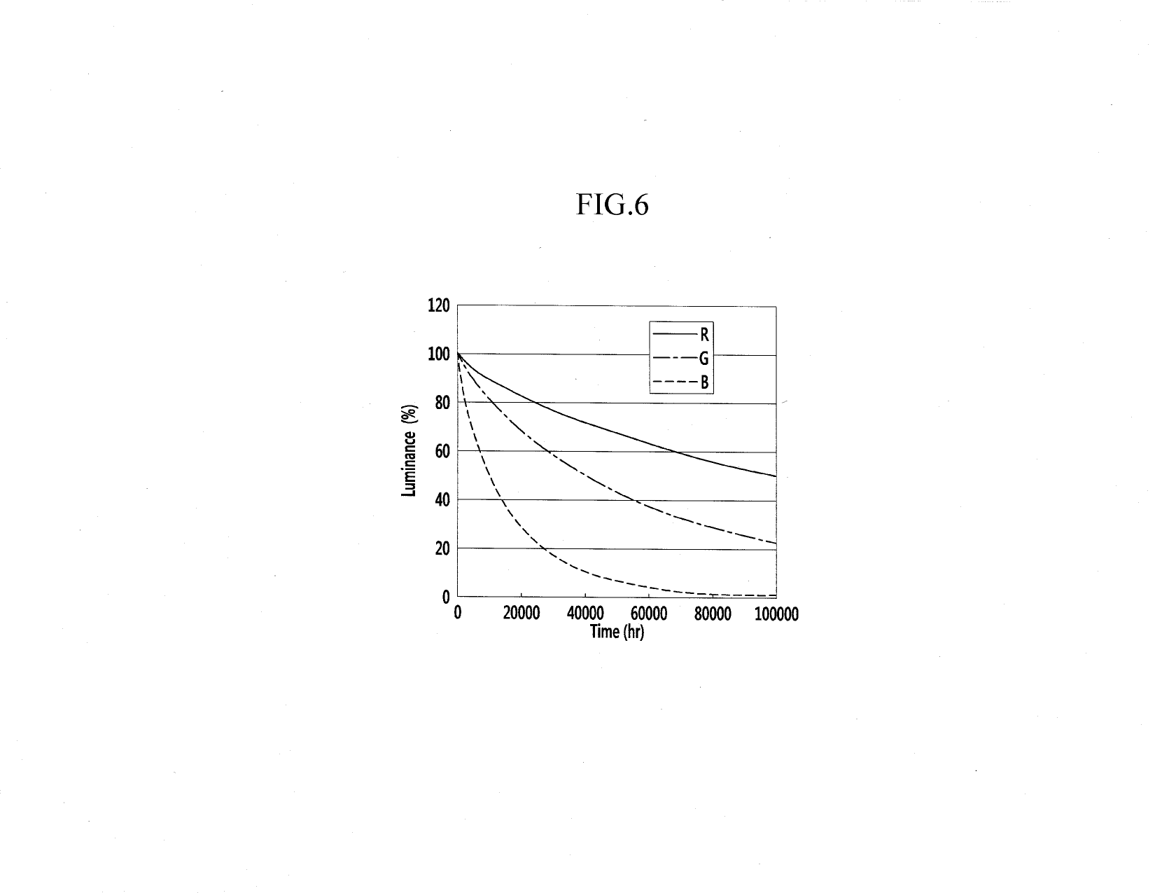

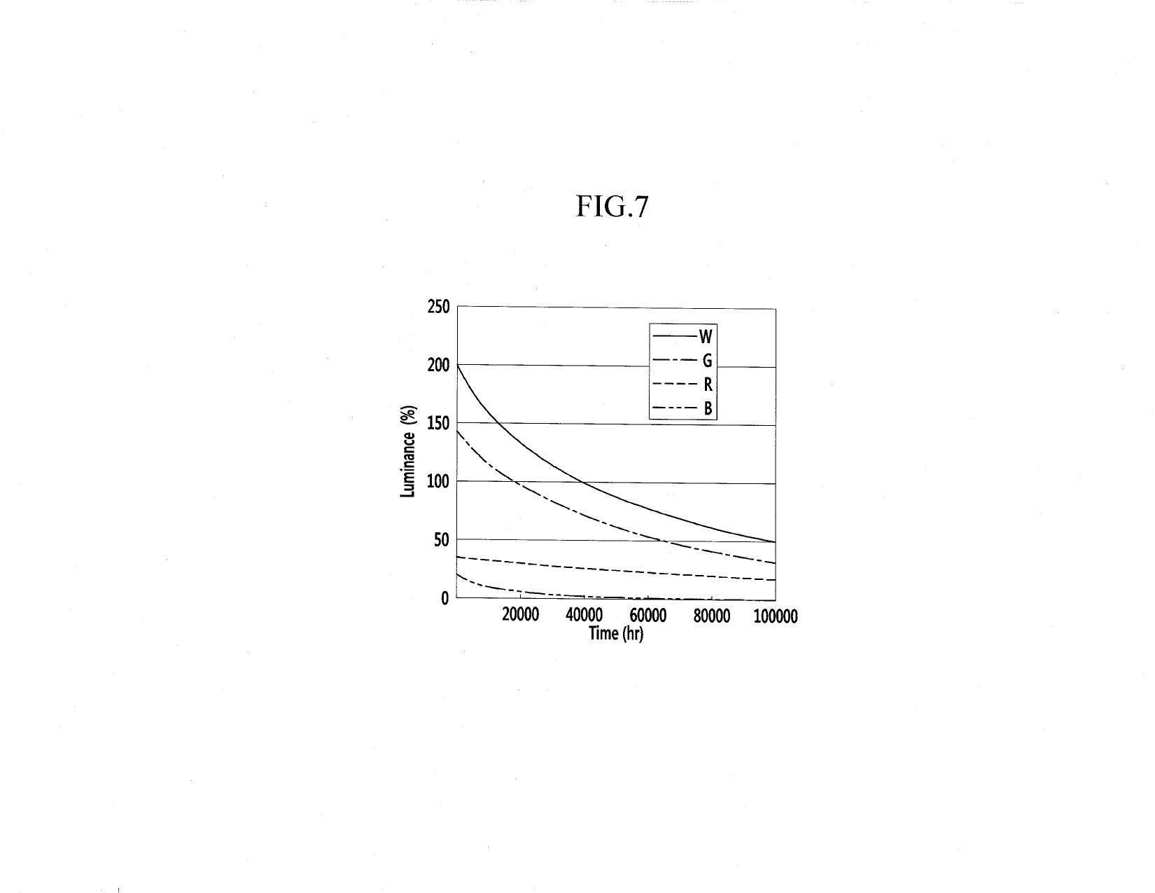

FIG. 6 is a graph showing a change of luminance according to time of each subpixel in a comparative display device including a red subpixel, a green subpixel, and a blue subpixel, and FIG. 7 is a graph showing a change of luminance according to time of a pixel under full white in the display device of FIG. 6.

The luminous efficiency and the life-span of the display device are the luminous efficiency and the life-span at a required luminance, and the required luminance means a luminance whereby the red subpixel, the green subpixel, and the blue subpixel emit light to form a full white FW in the display device. This required luminance is determined by a function of luminance of the FW display device, the color coordinates of the full white, each color coordinate of the red subpixel, the green subpixel, and the blue subpixel, each aperture ratio of the red subpixel, the green subpixel, and the blue subpixel, and the transmittance of the FW display device.

When the luminance of the FW display device is 200 nit (=cd/m²), each color coordinate of the full white, the red, the green, and the blue are FW (0.28 and 0.29), R (0.64 and 0.33), G (0.30 and 0.60), and B (0.16 and 0.50), each aperture ratio of the red subpixel, the green subpixel, and the blue subpixel are 13.3%, and the transmittance of the FW display device is 40%. The required luminance of light of the red subpixel, the required luminance of light of the green subpixel, and the required luminance of light of the blue subpixel are 681 nit, 2693 nit, and 385 nit, respectively. Also, the duty ratio of the red subpixel, the green subpixel, and the blue subpixel are all driven at 100%. The duty ratio means a ratio of a time that a pulse is in an on state for one period, and in a case of realizing the full white, a grayscale of the red subpixel, the green subpixel, and the blue subpixel is digital 256 colors, and a 255 maximum value is input and is maintained during one period.

A half life-span is a time that the required luminance of each subpixel is decreased to 50%, and as shown in FIG. 6, the half life-spans of the red subpixel, the green subpixel, and the blue subpixel are respectively 100,000 hr, 40,000 hr, and 10,000 hr.

At this time, as shown in FIG. 7, the half life-span of the FW display device is 40,000 hr, and as shown in Table 1 below, the luminous efficiency is 23.9 cd/A.

TABLE 1

| | Luminous efficiency (cd/A) | Voltage (V) | Power (W) |
|---|---|---|---|
| R | 43.0 | 4.2 | 0.96 |
| G | 43.7 | 3.6 | 3.2 |
| B | 4.8 | 3.9 | 4.51 |
| FW | 23.9 | | 8.67 |

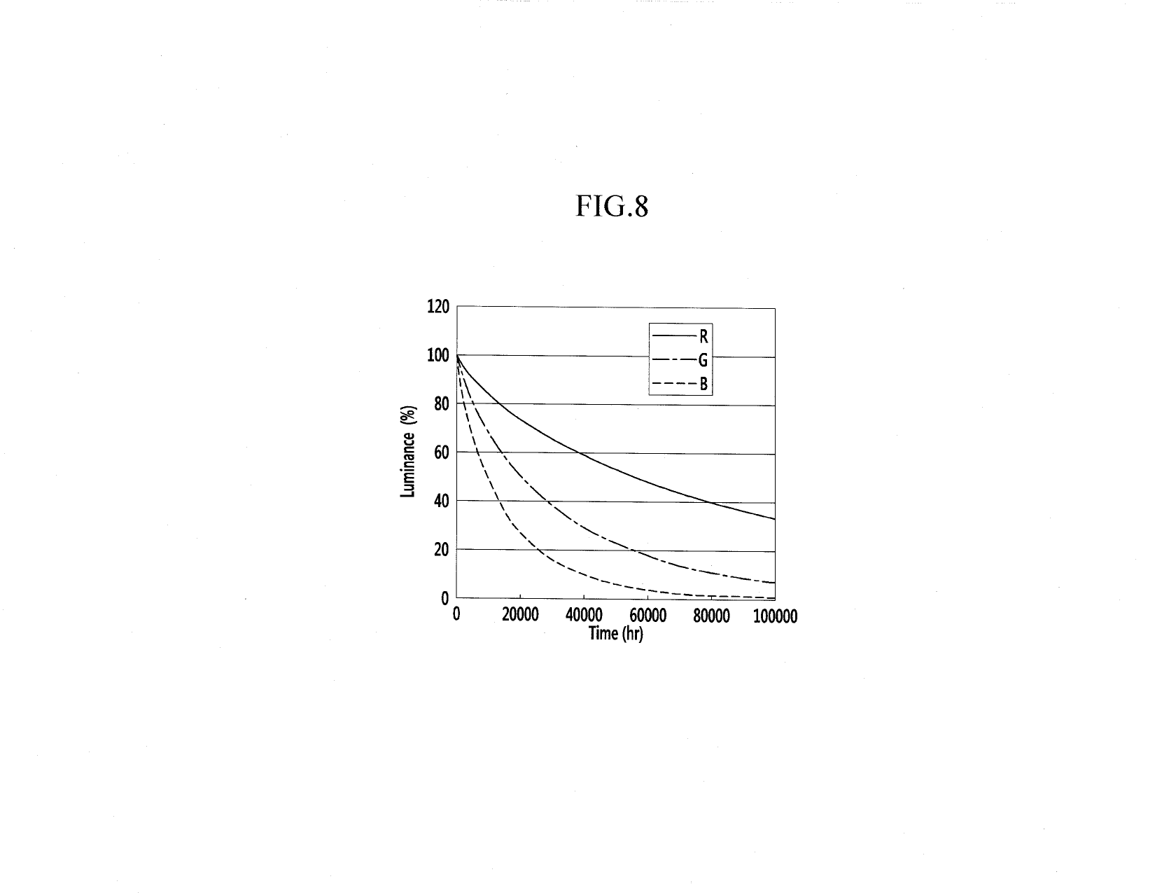

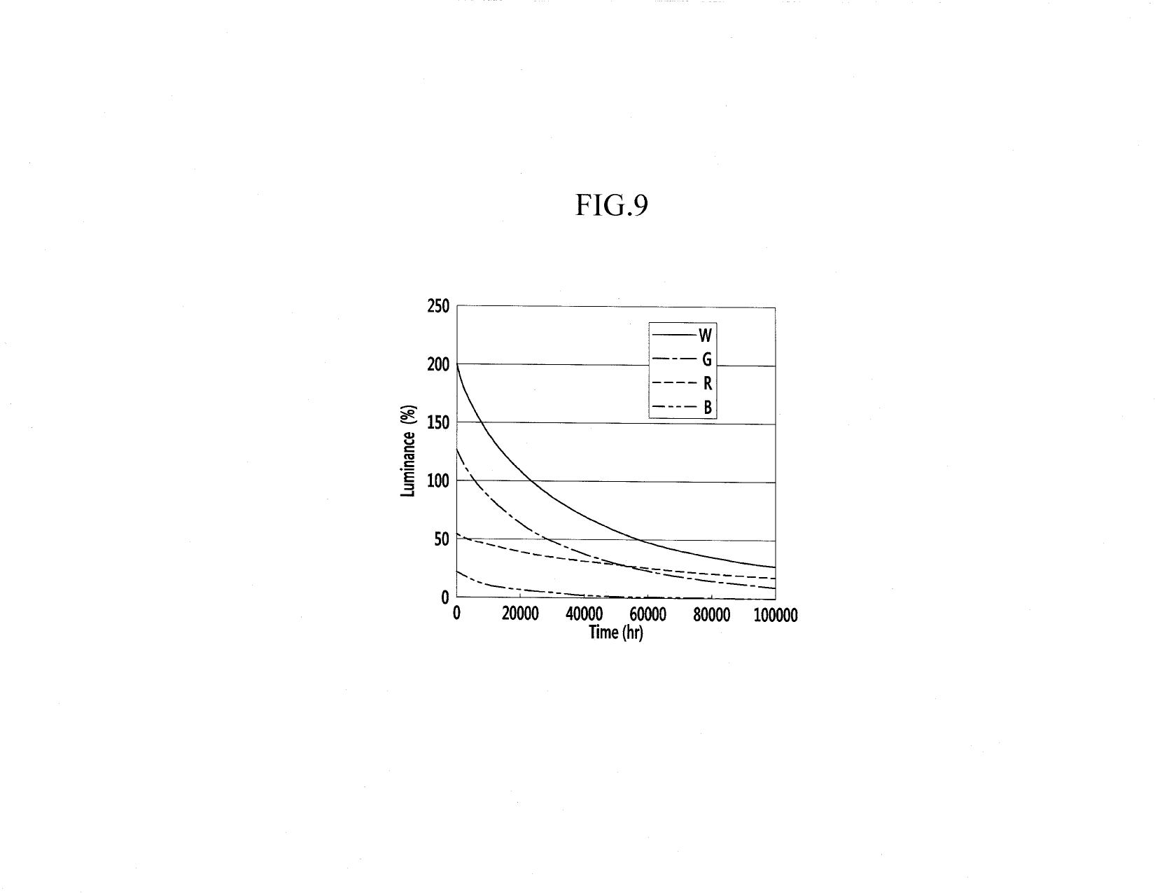

FIG. 8 is a graph showing a change of luminance according to time of each subpixel in a display device including a red subpixel, a deep green subpixel, and a blue subpixel, and FIG. 9 is a graph showing a change of a luminance according to time of a pixel under a full white in the display device of FIG. 8.

When the luminance of the FW display device is 200 nit (=cd/m2), each color coordinate of the full white, the red, the deep green, and the blue is FW (0.28 and 0.29), R (0.64 and 0.33), dG (0.21 and 0.71), B (0.16 and 0.50), each aperture ratio of the red subpixel, the deep green subpixel, and the blue subpixel is 13.3%, and the transmittance of the FW display device is 40%. The required luminance of light of the red subpixel, the required luminance of light of the deep green subpixel, and the required luminance of light of the blue subpixel are 1000 nit, 2363 nit, and 396 nit, respectively. At this time, the color coordinates of the deep green satisfy the standard colorimetric range of the NTSC standard. Also, the duty ratios at which the red subpixel, the deep green subpixel, and the blue subpixel are all driven are 100%. That is, in the case of realizing the full white, when the grayscale of the red subpixel, the deep green subpixel, and the blue subpixel is the digital 256 color, a 255 value as the maximum value is input and is maintained as it is during one period.

As shown in FIG. 8, the half life-span of the deep green subpixel is 20,000 hours at the required luminance of 2363 nit. At this time, as shown in FIG. 9, the half life-span of the FW display device is 23,000 hours, and as shown in Table 2 below, the luminous efficiency is 20.4 cd/A.

TABLE 2

| | Luminous efficiency (cd/A) | Voltage (V) | Power (W) |
|---|---|---|---|
| R | 39.8 | 4.6 | 1.66 |
| G | 30.7 | 3.9 | 4.30 |
| B | 4.8 | 4.0 | 4.73 |
| FW | 20.4 | | 10.69 |

As described above, when forming the deep green subpixel instead of the green subpixel, the color purity may be increased, however the luminous efficiency and the life-span may be deteriorated.

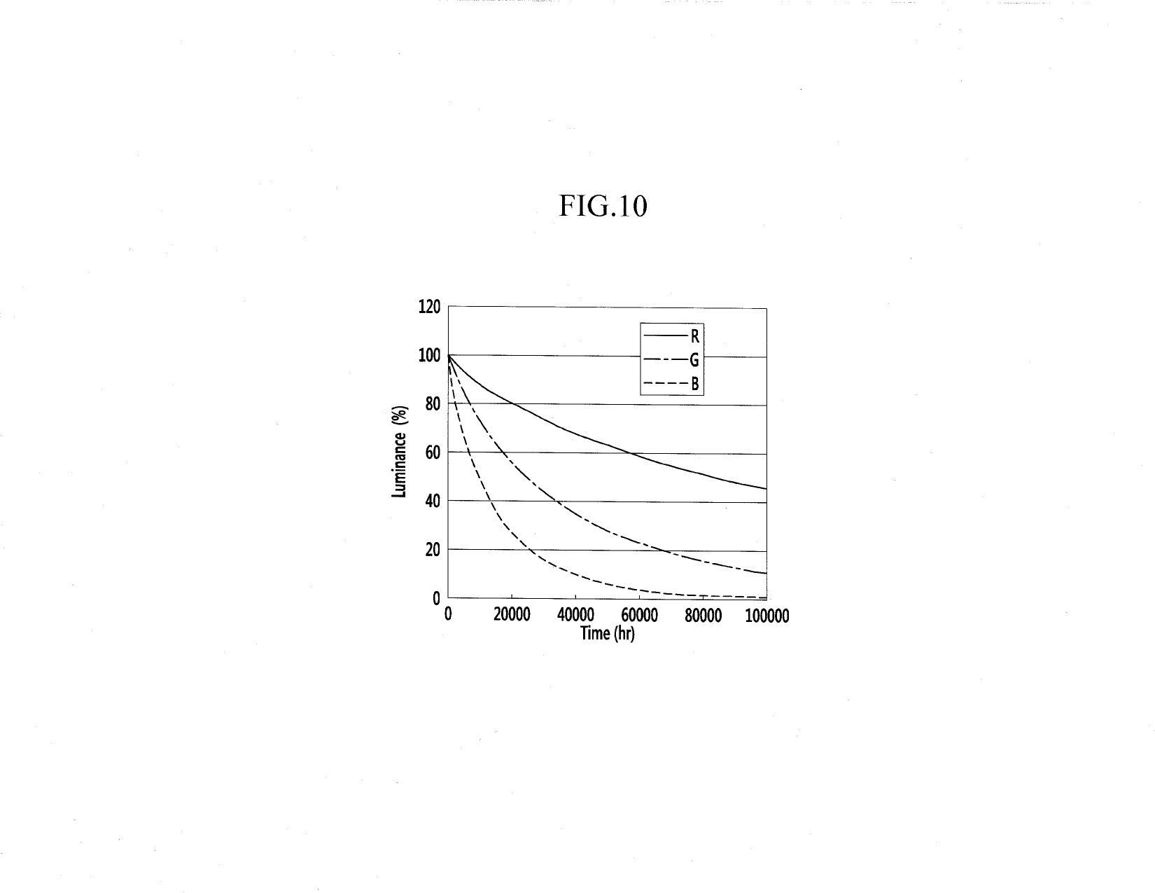

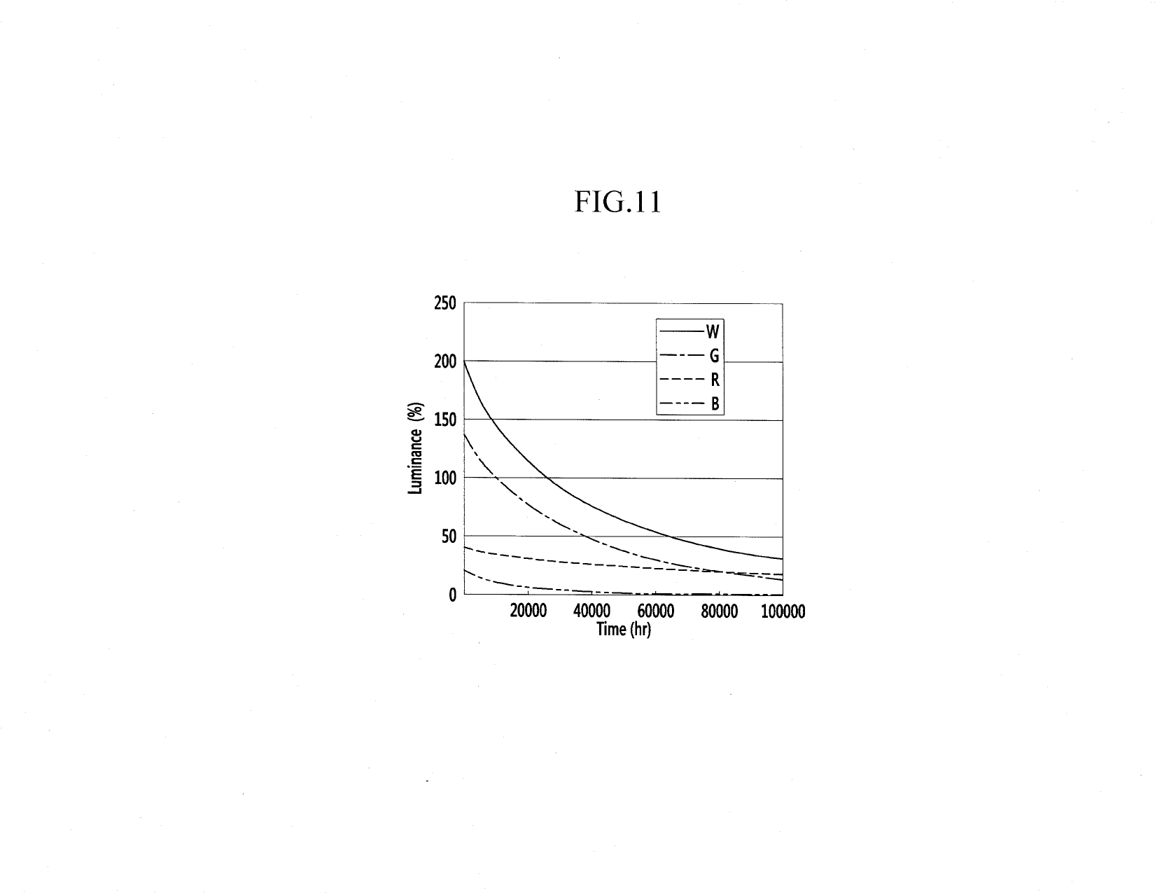

FIG. 10 is a graph showing a change of luminance according to time of each subpixel in a display device according to the first embodiment including a red subpixel, a green subpixel, a deep green subpixel, and a blue subpixel, and FIG. 11 is a graph showing a change of luminance according to time of a pixel under full white in the display device of FIG. 10. The green subpixel and the deep green subpixel are indicated by the same line in FIG. 10.

The duty ratio of the deep green subpixel is 25%, the duty ratio of the green subpixel is 75%, the aperture ratio of the deep green subpixel is 7.6%, and the aperture ratio of the green subpixel is 5.7%.

In a state of the deep green subpixel of 25% duty, luminance of the red pixel and luminance of the blue pixel are 681 nit and 385 nit, respectively. And in a state of the green subpixel of 75% duty, luminance of the red pixel and luminance of the blue pixel are 1000 nit and 396 nit, respectively. Accordingly, average luminance of the red pixel and average luminance of the blue pixel are 920 nit and 393 nit, respectively, and half life-span of the red pixel and half life-span of the blue pixel are 64,000 hours and 9600 hours, respectively.

The required luminance of the green subpixel and the required luminance of the deep green subpixel are 4713 nit and 5514 nit, respectively. The half life-spans are respectively 18,300 hours and 6100 hours. And as shown in FIG. 10, the half life-span of each of the green subpixel and the deep green subpixel considering the duty ratio is 24,400 hours. At this time, as shown in FIG. 11, the half life-span of the FW display device is 27,000 hours, and as shown in Table 3 below, the luminous efficiency is 23.0 cd/A.

TABLE 3

| | Luminous efficiency (cd/A) | Voltage (V) | Power (W) |
|---|---|---|---|
| R | 42.2 | 4.3 | 1.14 |
| G | 40.5 | 3.7 | 3.48 |
| B | 4.8 | 3.9 | 4.57 |
| FW | 23.0 | | 9.18 |

As described above, the luminous efficiency and the life-span of the display device according to the first embodiment including the red subpixel, the green subpixel, the deep green subpixel, and the blue subpixel are higher than the luminous efficiency and the life-span of the display device including the red subpixel, the deep green subpixel, and the blue subpixel, and are lower than the luminous efficiency and the life-span of the display device including the red subpixel, the green subpixel, and the blue subpixel.

As described above, the display device according to the first embodiment including the green subpixel and the deep green subpixel may have the high luminous efficiency and life-span of the display device only including the green subpixel and the high color purity of the display device only including the deep green subpixel.

Meanwhile, in the first embodiment, the red subpixel R, the green subpixel G, the deep green subpixel dG, and the blue subpixel B are arranged in the stripe type arrangement, however they may be applied to the second embodiment arranged in a square type arrangement or the third embodiment arranged in a pentile type arrangement.

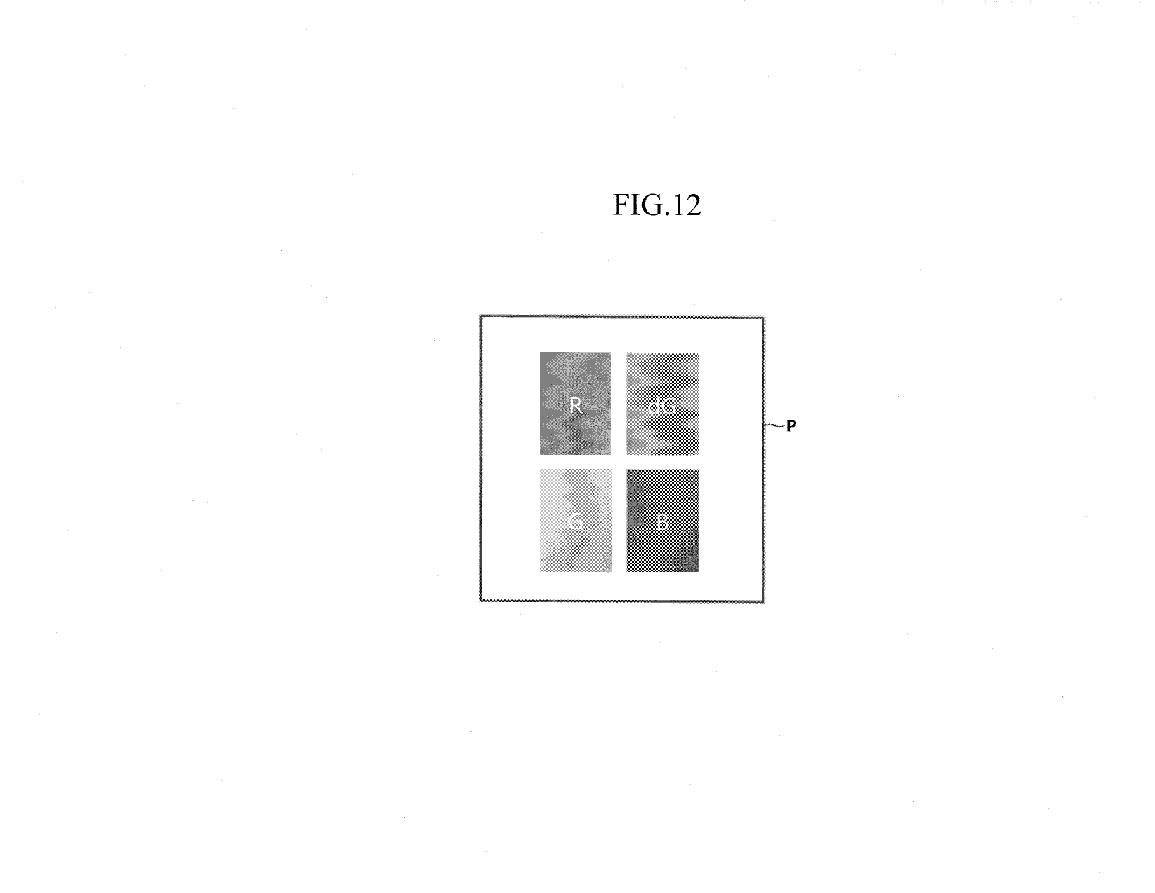

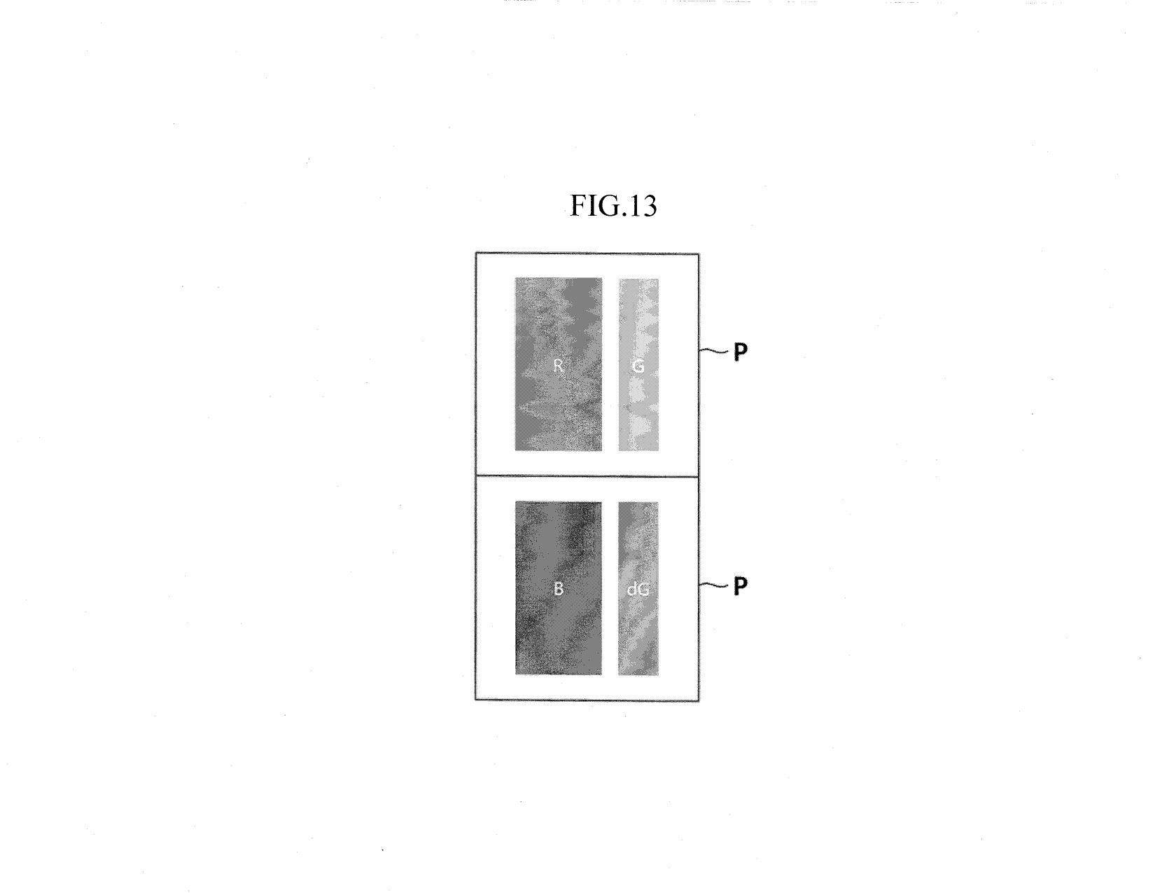

Next, referring to FIG. 12 and FIG. 13, a display device according to the second embodiment and the third embodiment will be described.

FIG. 12 is a top plan view of one pixel of a display device according to the second embodiment, and FIG. 13 is a top plan view of two pixels of a display device according to the third embodiment.

The second embodiment and the third embodiment shown in FIG. 12 and FIG. 13, except for an arrangement structure of the subpixel, are substantially equivalent to the first embodiment shown in FIG. 1 such that the repeated description thereof is omitted.

As shown in FIG. 12, a red subpixel R, a green subpixel G, a deep green subpixel dG, and a blue subpixel B of a display device according to the second embodiment are disposed with a quadrangle type (a rectangular type). That is, the red subpixel R, the green subpixel G, the deep green subpixel dG, and the blue subpixel B respectively have a rectangular shape and are gathered with a checked shape to form the pixel P of the square.

In the display device according to the second embodiment, the red subpixel R, the green subpixel G, the deep green subpixel dG, and the blue subpixel B are focused compared with the first embodiment such that it is easy to realize the full white.

As shown in FIG. 13, the red subpixel R and the green subpixel G of the display device according to the third embodiment form one pixel P, and the deep green subpixel dG and the blue subpixel B are disposed with the pentile type forming one pixel P so as to be driven with rendering. In the rendering driving, when displaying the images, the red, the green, the deep green, and the blue subpixel are independently driven, and simultaneously the subpixels positioned near the subpixel to be driven are driven together such that the brightness is dispersed along with the surrounding subpixel to display one pixel, thereby further delicately expressing an oblique line or a curved line and simultaneously controlling resolution.

Meanwhile, in the first embodiment, the deep green organic emission layer 720dG is formed at the deep green subpixel dG, however the fourth embodiment forming the deep green color filter at the deep green subpixel dG or the fifth embodiment forming the microcavity at the deep green subpixel dG are possible.

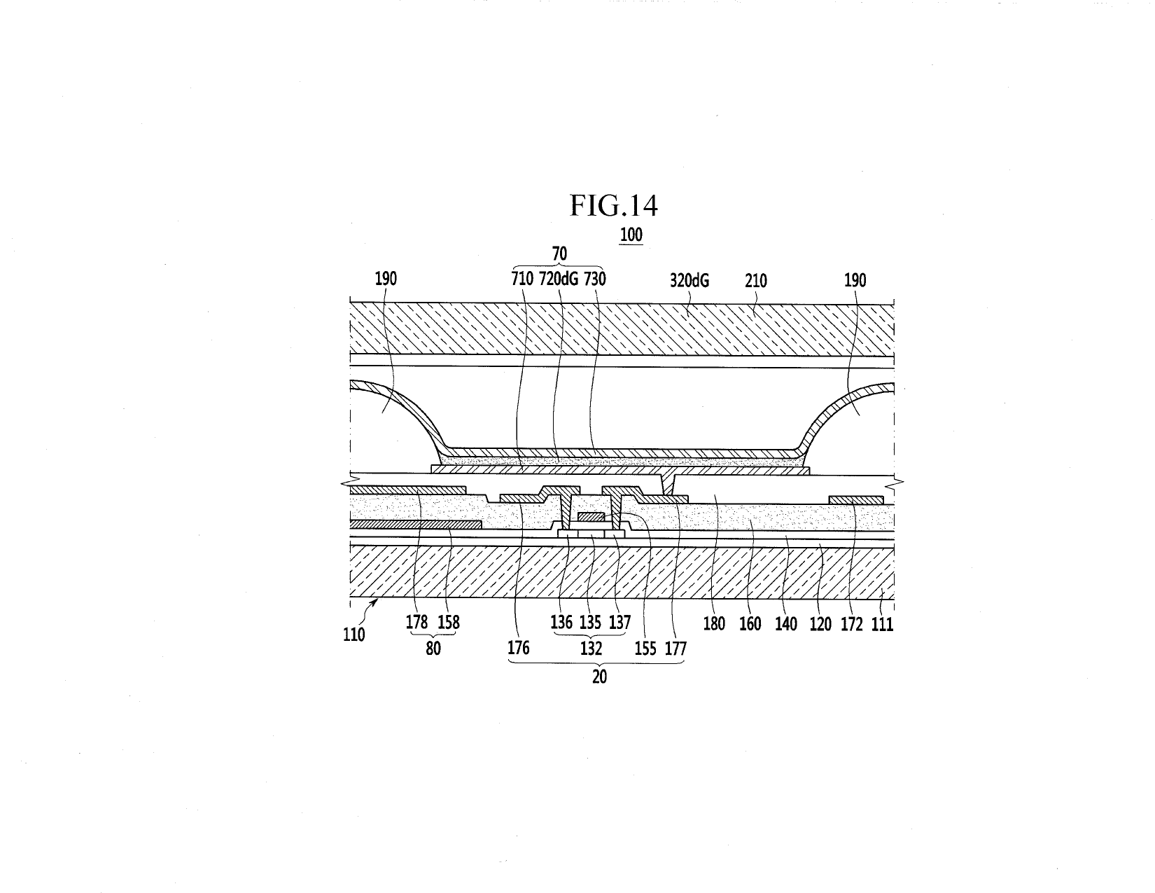

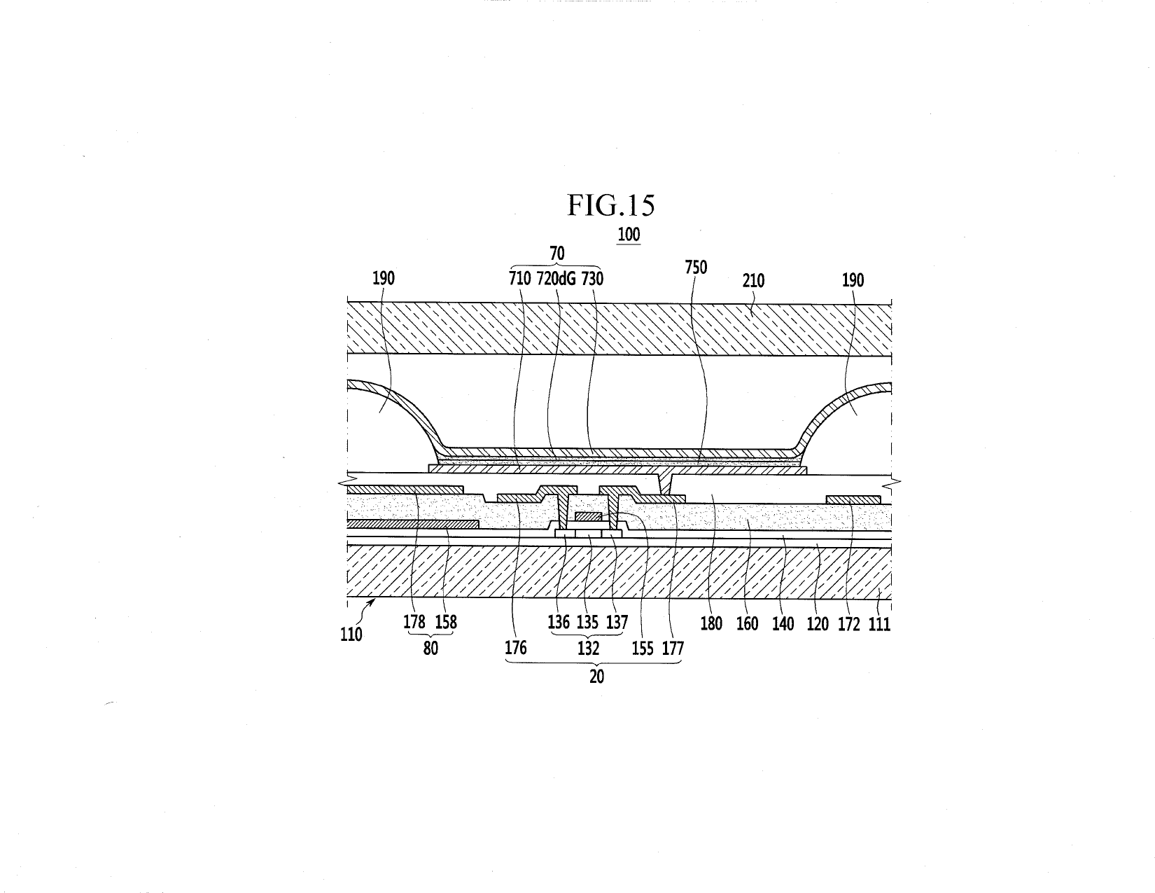

Next, referring to FIG. 14 and FIG. 15, display devices according to the fourth embodiment and the fifth embodiment will be described.

FIG. 14 is a cross-sectional view of a deep green subpixel of a display device according to the fourth embodiment, and FIG. 15 is a cross-sectional view of a deep green subpixel of a display device according to the fifth embodiment.

The fourth embodiment and the fifth embodiment shown in FIG. 14 and FIG. 15 are substantially equivalent to the first embodiment shown in FIG. 3 and FIG. 4 except for the deep green color filter or the microcavity formed at the deep green subpixel dG such that the repeated description is omitted.

As shown in FIG. 14, in the display device according to the fourth embodiment, in the deep green subpixel, the organic emission layer 720 is formed on the first electrode 710 and the second electrode 730 is formed on the organic emission layer 720. In embodiments, the pixel includes a red organic emission layer 720R positioned at a red subpixel R, a first green organic emission layer 720G positioned at the green subpixel G, a second green organic emission layer 720dG positioned at the deep green subpixel dG, and a blue organic emission layer 720B positioned at the blue subpixel B. At this time, the first green organic emission layer 720G and the second green organic emission layer 720dG emit light of the same color coordinate. Also, in the deep green subpixel, an encapsulation substrate 210 is arranged opposite to the display substrate 110 on the second electrode 730, and a deep green color filter 320dG is formed between the second electrode 730 and the encapsulation substrate 210. The deep green color filter 320dG filters the light such that the deep green having the high color purity is emitted. The deep green light emitted from the deep green color filter 320dG satisfies Equation 1 or Equation 2.

Meanwhile, as shown in FIG. 15, in the display device according to the fifth embodiment, in the deep green subpixel, an organic emission layer 720 is formed on the first electrode 710, and the second electrode 730 is formed on the organic emission layer 720. In embodiments, the pixel includes a red organic emission layer 720R positioned at the red subpixel R, a first green organic emission layer 720G positioned at the green subpixel G, a second green organic emission layer 720dG positioned at the deep green subpixel dG, and a blue organic emission layer 720B positioned at the blue subpixel B. At this time, light of the same color coordinates is emitted from the first green organic emission layer 720G and the second green organic emission layer 720dG. Also, in the deep green subpixel, a microcavity structure 750 is formed between the first electrode and the second deep green organic emission layer 720dG. The microcavity structure 750 reinforces the wavelength corresponding to the deep green such that the deep green having the high color purity is emitted through filtering. The deep green light emitted from the deep green subpixel dG through the microcavity structure 750 satisfies Equation 1 or Equation 2.

An embodiment provides the organic light emitting diode (OLED) display, however it is not limited thereto, and the present invention may be applied to a current type of display device such as a field effect display (FED).

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
a substrate; and
a pixel comprising a red subpixel, a green subpixel, a deep green subpixel, and a blue subpixel formed over the substrate.

2. The display device of claim 1, wherein the pixel comprises:
at least a first electrode formed over the substrate, and
a plurality of organic emission layers formed over the at least a first electrode, the plurality of organic emission layers comprising a red organic emission layer positioned at the red subpixel, a green organic emission layer positioned at the green subpixel, a deep green organic emission layer positioned at the deep green subpixel, and a blue organic emission layer positioned at the blue subpixel, and
at least a second electrode formed over the plurality of organic emission layers.

3. The display device of claim 2, wherein
the green organic emission layer is configured to emit green light having a y-axis color coordinate Gy greater than about 0.45, and
the deep green organic emission layer is configured to emit deep green light having a y-axis color coordinate dGy which satisfies dGy≧Gy+0.01.

4. The display device of claim 2, wherein
the green organic emission layer is configured to emit green light having a y-axis color coordinate Gy greater than about 0.45, and
the deep green organic emission layer is configured to emit deep green light having an x-axis color coordinate dGx which satisfies Gx≧dGx+0.01, where Gx is an x-axis color coordinate of the green light emitted from the green organic emission layer.

5. The display device of claim 2, wherein
the green organic emission layer is configured to emit green light having a peak wavelength λpg of the green light's spectrum and the deep green organic emission layer is configured to emit deep green light having a peak wavelength λpdg of the deep green light's spectrum,
wherein the peak wave lengths λpg and λpdg satisfies λpg−λpdg≧1 nm.

6. The display device of claim 2, wherein
the green organic emission layer is configured to emit green light having a spectrum width Wg which is a full width at quarter maximum (FWQM) of the green light's spectrum, and the deep green organic emission layer is configured to emit deep green light having a spectrum width Wdg which is a FWQM of the deep green light's spectrum,
wherein the spectrum widths Wg and Wdg satisfies Wg−Wdg≧1 nm.

7. The display device of claim 2, wherein
the green organic emission layer is configured to emit green light having a spectrum half width Whg which is a full width at half maximum (FWHM) of the green light's spectrum, and the deep green organic emission layer is configured to emit deep green light having a spectrum half width Whdg which is a FWHM of the deep green light's spectrum,
wherein the spectrum half widths Whg and Whdg satisfies Whg−Whdg≧1 nm.

8. The display device of claim 2, wherein
the green organic emission layer comprises a phosphor material or a phosphorescent material, and the deep green organic emission layer comprises a phosphor material or a phosphorescent material.

9. The display device of claim 2, wherein:
the deep green organic emission layer comprises a quantum dot.

10. The display device of claim 1, wherein the pixel comprises:
at least a first electrode formed over the substrate,
a plurality of organic emission layers formed over the at least a first electrode, the plurality of organic emission layers comprising a red organic emission layer positioned at the red subpixel, a first green organic emission layer positioned at the green subpixel, a second green organic emission layer positioned at the deep green subpixel, and a blue organic emission layer positioned at the blue subpixel,
at least a second electrode formed over the plurality of organic emission layers, and
a deep green color filter formed over the second green emission layer positioned at the deep green subpixel.

11. The display device of claim 1, wherein the pixel comprises:
at least a first electrode formed over the substrate,
a plurality of organic emission layers formed over the at least a first electrode, the plurality of organic emission layers comprising a red organic emission layer positioned at the red subpixel, a first green organic emission layer positioned at the green subpixel, a second green organic emission layer positioned at the deep green subpixel, and a blue organic emission layer positioned at the blue subpixel,
at least a second electrode formed over the plurality of organic emission layers, and
a microcavity structure formed between the at least a first electrode and the second green organic emission layer positioned at the deep green subpixel.

12. The display device of claim 1, wherein
one of the red subpixel, the green subpixel, the deep green subpixel, and the blue subpixel has area different from that of another subpixel.

13. The display device of claim 1, wherein
the red subpixel, the green subpixel, the deep green subpixel, and the blue subpixel are shaped and arranged such that the pixel has one selected from a stripe type arrangement, a quadrangle type arrangement, and a pentile type arrangement.
